(19) United States
(12) Patent Application Publication
(10) Pub. No.: US 2023/0366967 A1
(43) Pub. Date: Nov. 16, 2023

(54) IMAGING PHANTOM

(71) Applicant: The Regents of the University of Michigan, Ann Arbor, MI (US)

(72) Inventor: Scott D. Swanson, Ann Arbor, MI (US)

(21) Appl. No.: 18/196,229

(22) Filed: May 11, 2023

Related U.S. Application Data
(60) Provisional application No. 63/342,398, filed on May 16, 2022.

(51) Int. Cl. G01R 33/58

(52) U.S. Cl. CPC G01R 33/58

(57) ABSTRACT

Provided herein is technology relating to medical imaging and particularly, but not exclusively, to devices, methods, systems, and kits for validating medical imaging using an imaging phantom.

This application claims priority to U.S. provisional patent application Ser. No. 63/342,398, filed May 16, 2022, which is incorporated herein by reference in its entirety.

### STATEMENT REGARDING FEDERALLY SPONSORED RESEARCH OR DEVELOPMENT

This invention was made with government support under CA166104 awarded by the National Institutes of Health. The government has certain rights in the invention.

### FIELD

Provided herein is technology relating to medical imaging and particularly, but not exclusively, to devices, methods, systems, and kits for validating medical imaging using an imaging phantom.

### BACKGROUND

Quantitative measures of magnetic resonance imaging (MRI) parameters such as the spin-lattice relaxation time (T1) and the spin-spin relaxation time (T2) are becoming increasingly important for medical imaging. In particular, multisite studies using such quantitative MRI measurements for evaluating cancer, multiple sclerosis, myocardial disease, cartilage degradation, and other pathologies require calibrating, standardizing, and validating MRI systems of different types installed in different locations. In addition, artificial intelligence methods are increasingly used in magnetic resonance for parameter estimation. Accordingly, medical imaging needs quantitative MRI phantoms to validate MRI systems and algorithms used in MRI methods. However, most MRI phantoms in current use comprise paramagnetic ions (e.g., manganese, gadolinium, or nickel) at a range of concentrations to provide a range of T1 and T2 times typically found in vivo. While conventional paramagnetic ion phantoms are useful, they exhibit a monoexponential recovery or decay of magnetization whereas behavior in tissue is typically biexponential. Accordingly, phantoms exhibiting behavior in MRI similar to biological tissues are needed.

### SUMMARY

Accordingly, provided herein is a technology related to improved MRI phantoms. In particular, the technology relates to MRI phantoms comprising non-paramagnetic molecular agents that exhibit T1 and T2 that are similar to biological tissues in vivo. The phantoms described herein provide more flexibility than phantoms comprising paramagnetic ions. For example, embodiments of the phantoms described herein can be tuned to mimic white matter, gray matter, cardiac tissue, articular cartilage, or other types of biological tissue. Further, the phantoms described herein can be configured to provide a quantitative phantom for T1, T2, T1rho, magnetization transfer, or to provide multiple T2 compartments with or without exchange as is found in myelin for myelin water fraction imaging.

For example, in some embodiments, the technology provides compositions that find use as magnetic resonance imaging phantoms. In some embodiments, phantoms comprise a composition comprising an alcohol and a surfactant in water, wherein the w/w concentration of the alcohol and surfactant combined is 5% to 35% (e.g., 5.0%, 5.5%, 6.0%, 6.5%, 7.0%, 7.5%, 8.0%, 8.5%, 9.0%, 9.5%, 10.0%, 10.5%, 11.0%, 11.5%, 12.0%, 12.5%, 13.0%, 13.5%, 14.0%, 14.5%, 15.0%, 15.5%, 16.0%, 16.5%, 17.0%, 17.5%, 18.0%, 18.5%, 19.0%, 19.5%, 20.0%, 20.5%, 21.0%, 21.5%, 22.0%, 22.5%, 23.0%, 23.5%, 24.0%, 24.5%, 25.0%, 25.5%, 26.0%, 26.5%, 27.0%, 27.5%, 28.0%, 28.5%, 29.0%, 29.5%, 30.0%, 30.5%, 31.0%, 31.5%, 32.0%, 32.5%, 33.0%, 33.5%, 34.0%, 34.5%, or 35.0% w/w). In some embodiments, the alcohol comprises an alkane chain of 10 to 25 carbons (e.g., 10, 11, 12, 13, 14, 15, 16, 17, 18, 19, 20, 21, 22, 23, 24, or 25 carbons). In some embodiments, the alcohol comprises an alkane chain of 16 or 18 carbons. In some embodiments, the alcohol is cetearyl alcohol. In some embodiments, the cetearyl alcohol comprises a 1:1 weight or molar ratio mixture of cetyl alcohol and stearyl alcohol. In some embodiments, the cetearyl alcohol comprises a mixture of cetyl alcohol and stearyl alcohol at a weight or molar ratio of from 1:3 to 3:1. In some embodiments, the compositions further comprise cholesterol (e.g., at a concentration of 10% to 15% w/w (e.g., 10.0%, 10.5%, 11.0%, 11.5%, 12.0%, 12.5%, 13.0%, 13.5%, 14.0%, 14.5%, or 15.0 w/w). In some embodiments, the compositions further comprise an acid (e.g., a weak acid such as, e.g., lactic acid, citric acid, malic acid, formic acid, acetic acid, oxalic acid, etc.) In some embodiments, the compositions further comprise a pH buffer. In some embodiments, the compositions further comprise a cross-linked dextran gel (e.g., SEPHADEX (e.g., G-10, G-25, G-50, or G-100 SEPHADEX)). In some embodiments, the temperature of the composition is approximately 20° C. to 55° C. (e.g., 20.0, 20.5, 21.0, 21.5, 22.0, 22.5, 23.0, 23.5, 24.0, 24.5, 25.0, 25.5, 26.0, 26.5, 27.0, 27.5, 28.0, 28.5, 29.0, 29.5, 30.0, 30.5, 31.0, 31.5, 32.0, 32.5, 33.0, 33.5, 34.0, 34.5, 35.0, 35.5, 36.0, 36.5, 37.0, 37.5, 38.0, 38.5, 39.0, 39.5, 40.0, 40.5, 41.0, 41.5, 42.0, 42.5, 43.0, 43.5, 44.0, 44.5, 45.0, 45.5, 46.0, 46.5, 47.0, 47.5, 48.0, 48.5, 49.0, 49.5, 50.0, 50.5, 51.0, 51.5, 52.0, 52.5, 53.0, 53.5, 54.0, 54.5, or 55.0° C.).

Furthermore, in some embodiments, the technology relates to methods. For example, in some embodiments, methods comprise mixing a surfactant and an alcohol in water, wherein the w/w concentration of the alcohol and surfactant combined is 5% to 35% (e.g., 5.0%, 5.5%, 6.0%, 6.5%, 7.0%, 7.5%, 8.0%, 8.5%, 9.0%, 9.5%, 10.0%, 10.5%, 11.0%, 11.5%, 12.0%, 12.5%, 13.0%, 13.5%, 14.0%, 14.5%, 15.0%, 15.5%, 16.0%, 16.5%, 17.0%, 17.5%, 18.0%, 18.5%, 19.0%, 19.5%, 20.0%, 20.5%, 21.0%, 21.5%, 22.0%, 22.5%, 23.0%, 23.5%, 24.0%, 24.5%, 25.0%, 25.5%, 26.0%, 26.5%, 27.0%, 27.5%, 28.0%, 28.5%, 29.0%, 29.5%, 30.0%, 30.5%, 31.0%, 31.5%, 32.0%, 32.5%, 33.0%, 33.5%, 34.0%, 34.5%, or 35.0% w/w). In some embodiments, methods further comprise heating the water prior to mixing. In some embodiments, methods further comprise heating the surfactant and alcohol prior to the mixing. In some embodiments, the alcohol comprises an alkane chain of 10 to 25 carbons (e.g., comprising 10, 11, 12, 13, 14, 15, 16, 17, 18, 19, 20, 21, 22, 23, 24, 25 carbons). In some embodiments, the alcohol comprises an alkane chain of 16 or 18 carbons. In some embodiments, the alcohol is cetearyl alcohol. In some embodiments, the cetearyl alcohol comprises a 1:1 weight or molar ratio mixture of cetyl alcohol and stearyl alcohol. In some embodiments, the cetearyl alcohol comprises a mixture of cetyl alcohol and stearyl alcohol at a weight or molar ratio of from 1:3 to 3:1. In some embodiments, methods further comprise mixing cholesterol into the composition. In some embodiments, the cholesterol concentration in the composition is 10% to 15% w/w (e.g., 10.0%, 10.5%, 11.0%, 11.5%, 12.0%, 12.5%, 13.0%, 13.5%, 14.0%, 14.5%, or 15.0 w/w). In some embodiments, methods further comprise mixing an acid an acid (e.g., a weak acid such as, e.g., lactic acid, citric acid, malic acid, formic acid, acetic acid, oxalic acid, etc.) into the composition. In some embodiments, methods comprise mixing a pH buffer into the composition. In some embodiments, methods comprise mixing a cross-linked dextran gel into the composition.

The technology provided herein finds use in a number of clinical and research applications. In particular, the technology provides a method of validating a magnetic resonance imaging apparatus or magnetic resonance imaging protocol. For example, methods comprise providing a composition comprising an alcohol and a surfactant in water, wherein the w/w concentration of the alcohol and surfactant combined is 5% to 35%; and recording magnetic resonance data using the composition and a magnetic resonance imaging apparatus. In some embodiments, the magnetic resonance data comprises a measure of magnetization transfer (MT), enhanced magnetization transfer (eMT), inhomogeneous magnetization transfer (ihMT), inhomogeneous magnetization transfer ratio (ihMTR), or magnetization transfer asymmetry (MTA) for the composition. In some embodiments, the magnetic resonance data comprises a quantitative measure of magnetization transfer (MT), enhanced magnetization transfer (eMT), inhomogeneous magnetization transfer (ihMT), inhomogeneous magnetization transfer ratio (ihMTR), or magnetization transfer asymmetry (MTA) for the composition. In some embodiments, methods further comprise comparing the magnetic resonance data to previous magnetic resonance data obtained for the same magnetic resonance imaging apparatus, for the same magnetic resonance imaging protocol, for a different magnetic resonance imaging apparatus, for a different magnetic resonance imaging protocol, or to previously published magnetic resonance data. In some embodiments, methods further comprise comparing the magnetic resonance data to magnetic resonance data obtained for a biological sample. In some embodiments, methods further comprise comparing the magnetic resonance data to magnetic resonance data obtained for a biological sample comprising neurons and/or neuroglia. In some embodiments, methods further comprise comparing the magnetic resonance data to magnetic resonance data obtained for a biological sample comprising white matter, gray matter, myelin, and/or cerebrospinal fluid. In some embodiments, methods further comprise comparing the magnetic resonance data to magnetic resonance data obtained for a biological sample comprising an astrocyte, a microglial cell, an ependymal cell, an oligodendrocyte, a satellite cell, and/or a Schwann cell.

The technology further provides embodiments of systems. For example, some embodiments of systems comprise a composition comprising an alcohol and a surfactant in water, wherein the w/w concentration of the alcohol and surfactant combined is 5% to 35%; and a magnetic resonance imaging apparatus. In some embodiments, systems comprise a software component comprising instructions for obtaining magnetic resonance data and/or calculating a magnetic resonance value that describes magnetization transfer (MT), enhanced magnetization transfer (eMT), inhomogeneous magnetization transfer (ihMT), inhomogeneous magnetization transfer ratio (ihMTR), or magnetization transfer asymmetry (MTA).

Some portions of this description describe the embodiments of the technology in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times to refer to these arrangements of operations as modules, without loss of generality. The described operations and their associated modules may be embodied in software, firmware, hardware, or any combinations thereof.

Certain steps, operations, or processes described herein may be performed or implemented with one or more hardware or software modules, alone or in combination with other devices. In some embodiments, a software module is implemented with a computer program product comprising a computer-readable medium containing computer program code, which can be executed by a computer processor for performing any or all steps, operations, or processes described.

In some embodiments, systems comprise a computer and/or data storage provided virtually (e.g., as a cloud computing resource). In particular embodiments, the technology comprises use of cloud computing to provide a virtual computer system that comprises the components and/or performs the functions of a computer as described herein. Thus, in some embodiments, cloud computing provides infrastructure, applications, and software as described herein through a network and/or over the internet. In some embodiments, computing resources (e.g., data analysis, calculation, data storage, application programs, file storage, etc.) are remotely provided over a network (e.g., the internet; and/or a cellular network).

Embodiments of the technology may also relate to an apparatus for performing the operations herein. This apparatus may be specially constructed for the required purposes and/or it may comprise a general-purpose computing device selectively activated or reconfigured by a computer program stored in the computer. Such a computer program may be stored in a non-transitory, tangible computer readable storage medium or any type of media suitable for storing electronic instructions, which may be coupled to a computer system bus. Furthermore, any computing systems referred to in the specification may include a single processor or may be architectures employing multiple processor designs for increased computing capability.

Additional embodiments will be apparent to persons skilled in the relevant art based on the teachings contained herein.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

These and other features, aspects, and advantages of the present technology will become better understood with regard to the following drawings.

FIG. 1 is a schematic showing a method for producing lamellar systems. Alcohol and surfactant are added to water to create lamellar layers. At low concentrations (e.g., approximately 0.5 to 2% w/w), these systems form unilamellar vesicles find use as Diffusion-Kurtosis phantoms (see, e.g., U.S. patent application Ser. No. 16/850,273, incorporated herein by reference). At higher concentrations of approximately 5 to 10% w/w (e.g., up to approximately 30% w/w semisolid), these systems form multilamellar structures that find use as tissue mimicking phantoms for quantifying T1, T2, and MT.

FIG. 2 is a schematic showing a nuclear magnetic resonance (NMR) pulse sequence to generate magnetization transfer (MT) and enhanced magnetization transfer (eMT) z-spectra. With (++) gradients or (−−) gradients, conventional MT spectra are generated. A difference between (++) and (−−) gives magnetization transfer asymmetry (MTA). With (+−) or (− +), enhanced MT spectra are produced and inhomogeneous magnetization transfer (ihMT) is computed as known in the art and as described herein (see, e.g., Examples). RF pulse duration was 5 ms and pulse amplitude was 13 μT. The RF train duration was 1 s.

FIG. 3 shows data from a magnetization transfer (MT) experiments using phantoms comprising 2% agarose. MT is generated by exchange between free water and water bound in the agarose double helix. Data from four MT studies are shown—all four studies produced the same MT profile indicating that agarose has minimal MT asymmetry and ihMT. All studies were done at 25° C. unless noted otherwise.

FIG. 4 shows data from MT experiments using phantoms comprising decanol and cetyltrimethyl ammonium bromide (CTAB). The MTA and ihMTR curves indicated that they have an opposite sign for negative frequencies and overlap for positive frequencies. Accordingly, the asymmetry is due to MTA and ihMTR is zero. At lower RF power levels (not shown) the asymmetry is clearly seen to arise from chemical shift between water and decanol CH₂ protons.

FIG. 5A to 5C show data from experiments indicating that the phantom semisolid component T2 can be controlled using alcohols having aliphatic chain lengths of 10 carbons (FIG. 5A), 12 carbons (FIG. 5B), and 16 carbons (FIG. 5C). As shown by FIG. 5A to 5C, phantoms comprising lower molecular weight alcohols have longer T2 values and narrower MT, eMT, and ihMTR linewidths; and phantoms comprising higher molecular weight alcohols have shorter T2 values and wider MT, eMT, and ihMTR linewidths. The data indicate that biomimetic phantoms can be produced with semisolid T2 values similar to those found in vivo by appropriate choice of materials. FIG. 5A shows data from MT experiments using phantoms comprising 1-decanol and CTAB. The maximum ihMT signal occurs at 8 kHz with a value of 11%. FIG. 5B shows data from MT experiments using phantoms comprising 1-dodecanol and CTAB. The maximum ihMT signal occurs at 16 kHz with a value of 3%. FIG. 5C shows data from MT experiments using phantoms comprising 1-hexadecanol (cetyl alcohol) and CTAB. The maximum ihMT signal occurs at 20 kHz with a value of 16%.

FIG. 6 shows data from MT experiments using phantoms comprising CA:SD:BTAC at 50° C. The data indicated that increasing the temperature from 25° C. to 50° C. affects the measured MT properties in several ways. First, MT increased—both the proton exchange rate (and cross-relaxation rate) increased and total MT increased. Second, MT asymmetry increased. Activation energies of hydroxyl and amide protons differ, resulting in an imbalance in the exchange rates and thus increased MT asymmetry. Finally, ihMTR decreased because increased molecular motions lower proton T1d and reduce ihMTR.

FIG. 7 shows data from MT experiments using phantoms comprising CA:SD:BTAC plus cholesterol. Cholesterol provides an additional hydroxyl proton for cross-relaxation and a different underlying chemical shift profile. Addition of the rigid cholesterol molecule increased MTA relative to pure CA:SD:BTAC shown in FIG. 5. The MT asymmetry of cholesterol is also very broad. ihMTR decreased as cholesterol stiffens the membrane and decreases proton T1d times, providing more efficient intermolecular spin diffusion in the lipid matrix.

FIG. 8A is a plot of data showing the recovery of water longitudinal magnetization in a typical inversion recovery experiment. This sample was made with 30% w/w cetearyl alcohol and behentrimonium methosulfate (CA-BTMS) in water. As in tissue, magnetization recovers in a biexponential manner. Water proton magnetization first recovers with rate fast rate constant λ⁺ from non-inverted solid component proton pool. After approximately 100 ms, water and solid proton magnetization are at thermal equilibrium and recover together with slow time constant λ⁻.

FIG. 8B is a plot of data showing short time behavior of the same sample for which data are shown in FIG. 8A. The trajectory of magnetization shown in the plot is similar to the trajectory of magnetization observed in biological tissues.

FIG. 9 is a plot of data comparing the MT in 2% w/w agarose and in a lamellar liquid crystal (LLC) phantom. Agarose is typically used as an MT phantom, but the data indicated that the LLC sample has more favorable MT properties. In this experiment, RF saturation is applied from −50 kHz to +50 kHz to create indirect saturation at frequencies greater than ±5 kHz off resonance. Direct saturation of water is seen near zero. The MT experiment provides information about the semisolid components of tissue that are not present in conventional MRI methods.

FIGS. 10A and 10B are plots of data showing the change in MT as a function of pH. MT is driven by proton exchange, which changes with pH. The amount of MT was controlled by adjusting sample pH.

FIG. 11A is a schematic showing the locations of MRI MT phantoms for which MRI data were collected as shown in FIG. 11B. MT phantoms were made with conventional components gelatin (G7.5, G10, and G15) and agarose (Ag 2% w/w). Additionally, the MT-Full LLC phantom (MT-F) described herein and both a 50% w/w solution of MT-F (MT 1/2) and a 25% w/w solution of MT-F (MT 1/4) were tested. Distilled water (DI) and manganese solutions (Mn) were used as negative controls.

FIG. 12 is a bar plot showing data collected from a Multisite study of the MT phantom at Mayo Clinic, Cincinnati Children's Hospital, and the University of Michigan. LLC MT-F, MT 1/2, and MT 1/4 provide more MT than conventional MT phantoms and an easily controllable amount of MT for validation of MT sequences.

FIG. 13A to 13F show a summary of applications in which embodiments of the phantoms described herein find use. At low concentrations, LLC materials may be used as diffusion-kurtosis phantoms (FIG. 13A and FIG. 13B), e.g., as described in U.S. patent application Ser. No. 16/850,273, incorporated herein by reference. At higher concentrations, LLC phantoms perform well as MT phantoms and can be made to have inhomogeneous MT properties (ihMT) (FIG. 13C and FIG. 13D). Inclusion of SEPHADEX provides two compartments with different T2 times, which is similar to white matter in vivo. This phantom thus provides a myelin water fraction (MWF) phantom (FIG. 13E and FIG. 13F).

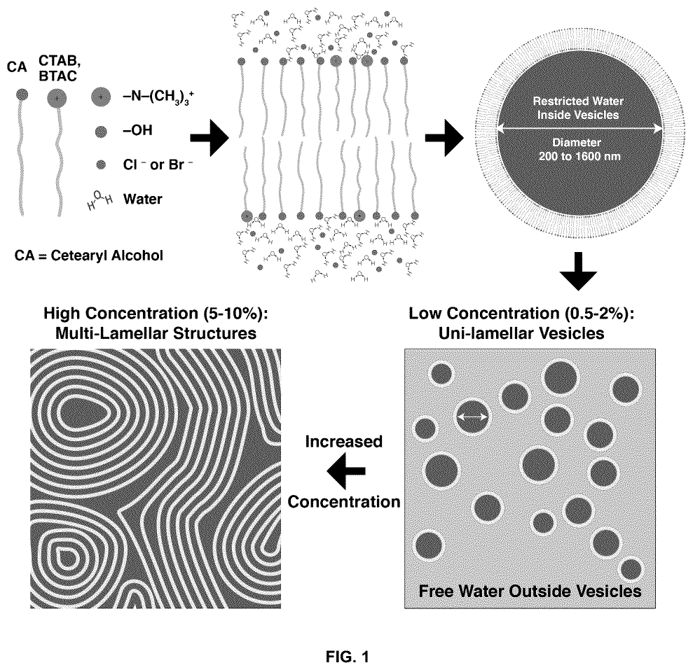

It is to be understood that the figures are not necessarily drawn to scale, nor are the objects in the figures necessarily drawn to scale in relationship to one another. The figures are depictions that are intended to bring clarity and understanding to various embodiments of apparatuses, systems, and methods disclosed herein. Wherever possible, the same reference numbers will be used throughout the drawings to refer to the same or like parts. Moreover, it should be appreciated that the drawings are not intended to limit the scope of the present teachings in any way.

### DETAILED DESCRIPTION

Provided herein is technology relating to medical imaging and particularly, but not exclusively, to devices, methods, systems, and kits for validating medical imaging using an imaging phantom.

In this detailed description of the various embodiments, for purposes of explanation, numerous specific details are set forth to provide a thorough understanding of the embodiments disclosed. One skilled in the art will appreciate, however, that these various embodiments may be practiced with or without these specific details. In other instances, structures and devices are shown in block diagram form. Furthermore, one skilled in the art can readily appreciate that the specific sequences in which methods are presented and performed are illustrative and it is contemplated that the sequences can be varied and still remain within the spirit and scope of the various embodiments disclosed herein.

All literature and similar materials cited in this application, including but not limited to, patents, patent applications, articles, books, treatises, and internet web pages are expressly incorporated by reference in their entirety for any purpose. Unless defined otherwise, all technical and scientific terms used herein have the same meaning as is commonly understood by one of ordinary skill in the art to which the various embodiments described herein belongs. When definitions of terms in incorporated references appear to differ from the definitions provided in the present teachings, the definition provided in the present teachings shall control. The section headings used herein are for organizational purposes only and are not to be construed as limiting the described subject matter in any way.

### Definitions

To facilitate an understanding of the present technology, a number of terms and phrases are defined below. Additional definitions are set forth throughout the detailed description.

Throughout the specification and claims, the following terms take the meanings explicitly associated herein, unless the context clearly dictates otherwise. The phrase “in one embodiment” as used herein does not necessarily refer to the same embodiment, though it may. Furthermore, the phrase “in another embodiment” as used herein does not necessarily refer to a different embodiment, although it may. Thus, as described below, various embodiments of the invention may be readily combined, without departing from the scope or spirit of the invention.

In addition, as used herein, the term “or” is an inclusive “or” operator and is equivalent to the term “and/or” unless the context clearly dictates otherwise. The term “based on” is not exclusive and allows for being based on additional factors not described, unless the context clearly dictates otherwise. In addition, throughout the specification, the meaning of “a”, “an”, and “the” include plural references. The meaning of “in” includes “in” and “on.”

As used herein, the terms “about”, “approximately”, “substantially”, and “significantly” are understood by persons of ordinary skill in the art and will vary to some extent on the context in which they are used. If there are uses of these terms that are not clear to persons of ordinary skill in the art given the context in which they are used, “about” and “approximately” mean plus or minus less than or equal to 10% of the particular term and “substantially” and “significantly” mean plus or minus greater than 10% of the particular term.

As used herein, disclosure of ranges includes disclosure of all values and further divided ranges within the entire range, including endpoints and sub-ranges given for the ranges. As used herein, the disclosure of numeric ranges includes the endpoints and each intervening number therebetween with the same degree of precision. For example, for the range of 6-9, the numbers 7 and 8 are contemplated in addition to 6 and 9, and for the range 6.0-7.0, the numbers 6.0, 6.1, 6.2, 6.3, 6.4, 6.5, 6.6, 6.7, 6.8, 6.9, and 7.0 are explicitly contemplated.

As used herein, the suffix “-free” refers to an embodiment of the technology that omits the feature of the base root of the word to which “-free” is appended. That is, the term “X-free” as used herein means “without X”, where X is a feature of the technology omitted in the “X-free” technology. For example, a “calcium-free” composition does not comprise calcium, a “mixing-free” method does not comprise a mixing step, etc.

Although the terms “first”, “second”, “third”, etc. may be used herein to describe various steps, elements, compositions, components, regions, layers, and/or sections, these steps, elements, compositions, components, regions, layers, and/or sections should not be limited by these terms, unless otherwise indicated. These terms are used to distinguish one step, element, composition, component, region, layer, and/or section from another step, element, composition, component, region, layer, and/or section. Terms such as “first”, “second”, and other numerical terms when used herein do not imply a sequence or order unless clearly indicated by the context. Thus, a first step, element, composition, component, region, layer, or section discussed herein could be termed a second step, element, composition, component, region, layer, or section without departing from technology.

As used herein, the word “presence” or “absence” (or, alternatively, “present” or “absent”) is used in a relative sense to describe the amount or level of a particular entity (e.g., component, action, element, analyte). For example, when an entity is said to be “present”, it means the level or amount of this entity is above a pre-determined threshold; conversely, when an entity is said to be “absent”, it means the level or amount of this entity is below a pre-determined threshold. The pre-determined threshold may be the threshold for detectability associated with the particular test used to detect the entity or any other threshold. When an entity is “detected” it is “present”; when an entity is “not detected” it is “absent”.

As used herein, an “increase” or a “decrease” refers to a detectable (e.g., measured) positive or negative change, respectively, in the value of a variable relative to a previously measured value of the variable, relative to a pre-established value, and/or relative to a value of a standard control. An increase is a positive change preferably at least 10%, more preferably 50%, still more preferably 2-fold, even more preferably at least 5-fold, and most preferably at least 10-fold relative to the previously measured value of the variable, the pre-established value, and/or the value of a standard control. Similarly, a decrease is a negative change preferably at least 10%, more preferably 50%, still more preferably at least 80%, and most preferably at least 90% of the previously measured value of the variable, the pre-established value, and/or the value of a standard control. Other terms indicating quantitative changes or differences, such as “more” or “less,” are used herein in the same fashion as described above.

As used herein, a “system” refers to a plurality of real and/or abstract components operating together for a common purpose. In some embodiments, a “system” is an integrated assemblage of hardware and/or software components. In some embodiments, each component of the system interacts with one or more other components and/or is related to one or more other components. In some embodiments, a system refers to a combination of components and software for controlling and directing methods. For example, a “system” or “subsystem” may comprise one or more of, or any combination of, the following: mechanical devices, hardware, components of hardware, circuits, circuitry, logic design, logical components, software, software modules, components of software or software modules, software procedures, software instructions, software routines, software objects, software functions, software classes, software programs, files containing software, etc., to perform a function of the system or subsystem. Thus, the methods and apparatus of the embodiments, or certain aspects or portions thereof, may take the form of program code (e.g., instructions) embodied in tangible media, such as floppy diskettes, CD-ROMs, hard drives, flash memory, or any other machine-readable storage medium wherein, when the program code is loaded into and executed by a machine, such as a computer, the machine becomes an apparatus for practicing the embodiments. In the case of program code execution on programmable computers, the computing device generally includes a processor, a storage medium readable by the processor (e.g., volatile and non-volatile memory and/or storage elements), at least one input device, and at least one output device. One or more programs may implement or utilize the processes described in connection with the embodiments, e.g., through the use of an application programming interface (API), reusable controls, or the like. Such programs are preferably implemented in a high-level procedural or object-oriented programming language to communicate with a computer system. However, the program(s) can be implemented in assembly or machine language, if desired. In any case, the language may be a compiled or interpreted language, and combined with hardware implementations.

Magnetization transfer and associated terms, techniques, concepts, and practice are described in, e.g., Battison and Cercignani “MT: Magnetisation Transfer”, chapter 10 in Quantitative MRI of the Brain (CRC Press Series in Medical Physics and Biomedical Engineering; Webster, Ritehour, Tabakov, and Ng, eds., New York, 2018, incorporated herein by reference). Use of ihMT for imaging white matter is described, e.g., in Swanson (2017) “Molecular, Dynamic, and Structural Origin of Inhomogeneous Magnetic Transfer in Lipid Membranes” Magnetic Resonance in Medicine 77: 1318-28, incorporated herein by reference. MT and ihMT technologies are described in, e.g., U.S. Pat. App. Pub. No. US20190033412A1, incorporated herein by reference.

### Compositions

In some embodiments, the phantoms described herein comprise surfactants and alcohols in water (e.g., high-molecular-weight surfactants and/or high-molecular-weight alcohols in water). In some embodiments, the phantoms comprise an emulsion of solid or semisolid in water. In some embodiments, the phantoms comprise total solid or semisolid (e.g., an alcohol (e.g., an alcohol comprising an alkane chain) and/or surfactant) concentrations between 5% and 35% w/w (e.g., 5.0%, 5.5%, 6.0%, 6.5%, 7.0%, 7.5%, 8.0%, 8.5%, 9.0%, 9.5%, 10.0%, 10.5%, 11.0%, 11.5%, 12.0%, 12.5%, 13.0%, 13.5%, 14.0%, 14.5%, 15.0%, 15.5%, 16.0%, 16.5%, 17.0%, 17.5%, 18.0%, 18.5%, 19.0%, 19.5%, 20.0%, 20.5%, 21.0%, 21.5%, 22.0%, 22.5%, 23.0%, 23.5%, 24.0%, 24.5%, 25.0%, 25.5%, 26.0%, 26.5%, 27.0%, 27.5%, 28.0%, 28.5%, 29.0%, 29.5%, 30.0%, 30.5%, 31.0%, 31.5%, 32.0%, 32.5%, 33.0%, 33.5%, 34.0%, 34.5%, or 35.0% w/w). In some embodiments, phantoms comprise water and a solid or semisolid (wax-like) component (e.g., an alcohol (e.g., an alcohol comprising an alkane chain) and/or surfactant) at a concentration of between 5% and 35% w/w (e.g., 5.0%, 5.5%, 6.0%, 6.5%, 7.0%, 7.5%, 8.0%, 8.5%, 9.0%, 9.5%, 10.0%, 10.5%, 11.0%, 11.5%, 12.0%, 12.5%, 13.0%, 13.5%, 14.0%, 14.5%, 15.0%, 15.5%, 16.0%, 16.5%, 17.0%, 17.5%, 18.0%, 18.5%, 19.0%, 19.5%, 20.0%, 20.5%, 21.0%, 21.5%, 22.0%, 22.5%, 23.0%, 23.5%, 24.0%, 24.5%, 25.0%, 25.5%, 26.0%, 26.5%, 27.0%, 27.5%, 28.0%, 28.5%, 29.0%, 29.5%, 30.0%, 30.5%, 31.0%, 31.5%, 32.0%, 32.5%, 33.0%, 33.5%, 34.0%, 34.5%, or 35.0% w/w).

In some embodiments, the phantoms comprise alcohols with alkane chains (e.g., comprising 10 to 25 carbons (e.g., comprising 10, 11, 12, 13, 14, 15, 16, 17, 18, 19, 20, 21, 22, 23, 24, 25 carbons)). In some embodiments, the phantoms comprise alcohols with alkane chains having 16 or 18 carbons. Data collected during the development and testing of embodiments of the technology described herein indicated that phantoms comprising alcohols with alkane chains have characteristics similar to biological tissues and thus the technology described herein provides a phantom that mimics the properties of biological tissues in vivo.

In some embodiments, the phantoms provided herein comprise an alcohol having an alkane chain of 10 to 25 carbons (e.g., comprising 10, 11, 12, 13, 14, 15, 16, 17, 18, 19, 20, 21, 22, 23, 24, 25 carbons) and a surfactant. In some embodiments, the surfactant is cetyltrimethyl ammonium bromide (CTAB), cocamidopropyl dimethylamine (CAPDMA), stearamidopropyl dimethylamine (SAPDMA), behenamidopropyl dimethylamine (BAPDMA), cetrimonium chloride (CTAC), behentrimethyl ammonium chloride (BTAC), behentrimonium methosulfate (BTMS), and mixtures of the foregoing, and the like. In some embodiments, the phantoms provided herein comprise the alcohol and the surfactant at a total concentration of 5 to 35% w/w (e.g., 5.0%, 5.5%, 6.0%, 6.5%, 7.0%, 7.5%, 8.0%, 8.5%, 9.0%, 9.5%, 10.0%, 10.5%, 11.0%, 11.5%, 12.0%, 12.5%, 13.0%, 13.5%, 14.0%, 14.5%, 15.0%, 15.5%, 16.0%, 16.5%, 17.0%, 17.5%, 18.0%, 18.5%, 19.0%, 19.5%, 20.0%, 20.5%, 21.0%, 21.5%, 22.0%, 22.5%, 23.0%, 23.5%, 24.0%, 24.5%, 25.0%, 25.5%, 26.0%, 26.5%, 27.0%, 27.5%, 28.0%, 28.5%, 29.0%, 29.5%, 30.0%, 30.5%, 31.0%, 31.5%, 32.0%, 32.5%, 33.0%, 33.5%, 34.0%, 34.5%, or 35.0% w/w) in water.

In some embodiments, the phantoms provided herein comprise solid and/or semisolid components that comprise cetyl alcohol (e.g., an alcohol comprising an alkane chain of 16 carbons) and stearyl alcohol (e.g., an alcohol comprising an alkane chain of 18 carbons). This mixture of cetyl alcohol and stearyl alcohol (“cetearyl alcohol”) inhibits and/or minimizes crystallization and maintains and/or maximizes liquid order, and it has properties similar to phospholipid membranes found in vivo. In some embodiments, the phantoms provided herein comprise cetyl alcohol and stearyl alcohol in approximately a 1:1 ratio (e.g., a “50/50” mixture of cetyl alcohol and stearyl alcohol). In some embodiments, the phantoms comprise other ratios of cetyl alcohol and stearyl alcohol ranging from approximately 1:3 to 1:1 to 3:1, e.g., in some embodiments, phantoms comprise a mixture of cetyl alcohol and stearyl alcohol comprising 30% to 70% (e.g., 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, or 70%) cetyl alcohol and, concomitantly, 70% to 30% (e.g., 70%, 69%, 68%, 67%, 66%, 65%, 64%, 63%, 62%, 61%, 60%, 59%, 58%, 57%, 56%, 55%, 54%, 53%, 52%, 51%, 50%, 49%, 48%, 47%, 46%, 45%, 44%, 43%, 42%, 41%, 40%, 39%, 38%, 37%, 36%, 35%, 34%, 33%, 32%, 31%, or 30%) stearyl alcohol such that the two percentages sum to 100%.

In some embodiments, phantoms comprising a surfactant and cetearyl alcohol provide a lamellar system of semisolids and water. In some embodiments, phantoms comprise a surfactant and a mixture of cetyl alcohol and stearyl alcohol comprising 30% to 70% (e.g., 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, or 70%) cetyl alcohol and, concomitantly, 70% to 30% (e.g., 70%, 69%, 68%, 67%, 66%, 65%, 64%, 63%, 62%, 61%, 60%, 59%, 58%, 57%, 56%, 55%, 54%, 53%, 52%, 51%, 50%, 49%, 48%, 47%, 46%, 45%, 44%, 43%, 42%, 41%, 40%, 39%, 38%, 37%, 36%, 35%, 34%, 33%, 32%, 31%, or 30%) stearyl alcohol such that the two percentages sum to 100%. Data collected during the development and testing of embodiments of the technology described herein indicated that magnetic interactions within the lamellar system are similar to the magnetic interactions that occur in vivo. Thus, phantoms comprising the molecular lamellar liquid crystal systems described herein provide realistic, biological tissue-like compositions on which to base phantoms for quantification of T1, T2, magnetization transfer, and T1rho.

In some embodiments, phantoms comprise cholesterol. In some embodiments, phantoms comprise cholesterol at approximately 10 to 15% w/w (e.g., 10.0%, 10.5%, 11.0%, 11.5%, 12.0%, 12.5%, 13.0%, 13.5%, 14.0%, 14.5%, or 15.0 w/w).

Accordingly, in some embodiments, the technology described herein provides a phantom comprising an alcohol having an alkane chain of 10 to 25 carbons (e.g., comprising 10, 11, 12, 13, 14, 15, 16, 17, 18, 19, 20, 21, 22, 23, 24, 25 carbons), a surfactant (e.g., cetyltrimethyl ammonium bromide (CTAB), cocamidopropyl dimethylamine (CAPDMA), stearamidopropyl dimethylamine (SAPDMA), behenamidopropyl dimethylamine (BAPDMA), cetrimonium chloride (CTAC), behentrimethyl ammonium chloride (BTAC), behentrimonium methosulfate (BTMS), or mixtures of the foregoing, and the like), and cholesterol in water. In some embodiments, the total concentration of the alcohol and surfactant in water is 5 to 35% w/w (e.g., 5.0%, 5.5%, 6.0%, 6.5%, 7.0%, 7.5%, 8.0%, 8.5%, 9.0%, 9.5%, 10.0%, 10.5%, 11.0%, 11.5%, 12.0%, 12.5%, 13.0%, 13.5%, 14.0%, 14.5%, 15.0%, 15.5%, 16.0%, 16.5%, 17.0%, 17.5%, 18.0%, 18.5%, 19.0%, 19.5%, 20.0%, 20.5%, 21.0%, 21.5%, 22.0%, 22.5%, 23.0%, 23.5%, 24.0%, 24.5%, 25.0%, 25.5%, 26.0%, 26.5%, 27.0%, 27.5%, 28.0%, 28.5%, 29.0%, 29.5%, 30.0%, 30.5%, 31.0%, 31.5%, 32.0%, 32.5%, 33.0%, 33.5%, 34.0%, 34.5%, or 35.0% w/w) in water and the concentration of cholesterol is 10 to 15% w/w (e.g., 10.0%, 10.5%, 11.0%, 11.5%, 12.0%, 12.5%, 13.0%, 13.5%, 14.0%, 14.5%, or 15.0 w/w) in water.

In some embodiments, the phantom is provided at a temperature that is room temperature, at 25° C., at 37° C., or at 50° C. Accordingly, in some embodiments, the phantoms are provided at a temperature that is from approximately 20° C. to 55° C. (e.g., 20.0, 20.5, 21.0, 21.5, 22.0, 22.5, 23.0, 23.5, 24.0, 24.5, 25.0, 25.5, 26.0, 26.5, 27.0, 27.5, 28.0, 28.5, 29.0, 29.5, 30.0, 30.5, 31.0, 31.5, 32.0, 32.5, 33.0, 33.5, 34.0, 34.5, 35.0, 35.5, 36.0, 36.5, 37.0, 37.5, 38.0, 38.5, 39.0, 39.5, 40.0, 40.5, 41.0, 41.5, 42.0, 42.5, 43.0, 43.5, 44.0, 44.5, 45.0, 45.5, 46.0, 46.5, 47.0, 47.5, 48.0, 48.5, 49.0, 49.5, 50.0, 50.5, 51.0, 51.5, 52.0, 52.5, 53.0, 53.5, 54.0, 54.5, or 55.0° C.).

In some embodiments, the phantom further comprises a pH buffer (e.g., a buffer to maintain a pH of approximately 2 to 8 (e.g., a pH of 2.0, 2.1, 2.2, 2.3, 2.4, 2.5, 2.6, 2.7, 2.8, 2.9, 3.0, 3.1, 3.2, 3.3, 3.4, 3.5, 3.6, 3.7, 3.8, 3.9, 4.0, 4.1, 4.2, 4.3, 4.4, 4.5, 4.6, 4.7, 4.8, 4.9, 5.0, 5.1, 5.2, 5.3, 5.4, 5.5, 5.6, 5.7, 5.8, 5.9, 6.0, 6.1, 6.2, 6.3, 6.4, 6.5, 6.6, 6.7, 6.8, 6.9, 7.0, 7.1, 7.2, 7.3, 7.4, 7.5, 7.6, 7.7, 7.8, 7.9, or 8.0) in the phantom composition).

In some embodiments, the phantom further comprises a cross-linked dextran gel (e.g., SEPHADEX (e.g., G-10 or G-50 SEPHADEX)).

### Methods

The technology also relates to methods of making and using a phantom as described herein. For example, in some embodiments, methods comprise mixing a surfactant and an alcohol in water. In some embodiments, methods comprising heating the surfactant and/or the alcohol to provide the surfactant and/or the alcohol as a liquid or semisolid. In some embodiments, methods comprising heating the surfactant and/or the alcohol to decrease the viscosity of the surfactant and/or the alcohol to facilitate addition of the surfactant and/or the alcohol to the water. In some embodiments, methods comprise heating the water and adding the surfactant and/or the alcohol to the heated water. In some embodiments, methods comprise heating water to provide hot water, melting solid and/or semisolid component(s) to provide melted solid and/or semisolid component(s), and adding the melted solid and/or semisolid component(s) to the hot water.

In some embodiments, methods comprise providing an alcohol having an alkane chain of 10 to 25 carbons (e.g., comprising 10, 11, 12, 13, 14, 15, 16, 17, 18, 19, 20, 21, 22, 23, 24, 25 carbons) and a surfactant (e.g., cetyltrimethyl ammonium bromide (CTAB), cocamidopropyl dimethylamine (CAPDMA), stearamidopropyl dimethylamine (SAPDMA), behenamidopropyl dimethylamine (BAPDMA), cetrimonium chloride (CTAC), behentrimethyl ammonium chloride (BTAC), behentrimonium methosulfate (BTMS), mixtures of the foregoing, and the like); and mixing the alcohol and surfactant in water to provide a total concentration of the alcohol and the surfactant in water that is approximately 5 to 35% w/w (e.g., 5.0%, 5.5%, 6.0%, 6.5%, 7.0%, 7.5%, 8.0%, 8.5%, 9.0%, 9.5%, 10.0%, 10.5%, 11.0%, 11.5%, 12.0%, 12.5%, 13.0%, 13.5%, 14.0%, 14.5%, 15.0%, 15.5%, 16.0%, 16.5%, 17.0%, 17.5%, 18.0%, 18.5%, 19.0%, 19.5%, 20.0%, 20.5%, 21.0%, 21.5%, 22.0%, 22.5%, 23.0%, 23.5%, 24.0%, 24.5%, 25.0%, 25.5%, 26.0%, 26.5%, 27.0%, 27.5%, 28.0%, 28.5%, 29.0%, 29.5%, 30.0%, 30.5%, 31.0%, 31.5%, 32.0%, 32.5%, 33.0%, 33.5%, 34.0%, 34.5%, or 35.0% w/w) in water. In some embodiments, methods comprise providing and/or mixing a pH buffer in the compositions comprising an alcohol and a surfactant.

In some embodiments, methods comprise providing an alcohol having an alkane chain of 10 to 25 carbons (e.g., comprising 10, 11, 12, 13, 14, 15, 16, 17, 18, 19, 20, 21, 22, 23, 24, 25 carbons) and a surfactant (e.g., cetyltrimethyl ammonium bromide (CTAB), cocamidopropyl dimethylamine (CAPDMA), stearamidopropyl dimethylamine (SAPDMA), behenamidopropyl dimethylamine (BAPDMA), cetrimonium chloride (CTAC), behentrimethyl ammonium chloride (BTAC), behentrimonium methosulfate (BTMS), mixtures of the foregoing, and the like); heating the alcohol and/or the surfactant; heating the water; and mixing the heated alcohol and/or surfactant in the heated water to provide a total concentration of the alcohol and the surfactant in water that is approximately 5 to 35% w/w (e.g., 5.0%, 5.5%, 6.0%, 6.5%, 7.0%, 7.5%, 8.0%, 8.5%, 9.0%, 9.5%, 10.0%, 10.5%, 11.0%, 11.5%, 12.0%, 12.5%, 13.0%, 13.5%, 14.0%, 14.5%, 15.0%, 15.5%, 16.0%, 16.5%, 17.0%, 17.5%, 18.0%, 18.5%, 19.0%, 19.5%, 20.0%, 20.5%, 21.0%, 21.5%, 22.0%, 22.5%, 23.0%, 23.5%, 24.0%, 24.5%, 25.0%, 25.5%, 26.0%, 26.5%, 27.0%, 27.5%, 28.0%, 28.5%, 29.0%, 29.5%, 30.0%, 30.5%, 31.0%, 31.5%, 32.0%, 32.5%, 33.0%, 33.5%, 34.0%, 34.5%, or 35.0% w/w) in water. In some embodiments, methods comprise providing and/or mixing a pH buffer in the compositions comprising an alkane and a surfactant.

In some embodiments, methods comprise providing an alcohol having an alkane chain of 10 to 25 carbons (e.g., comprising 10, 11, 12, 13, 14, 15, 16, 17, 18, 19, 20, 21, 22, 23, 24, 25 carbons), a surfactant (e.g., cetyltrimethyl ammonium bromide (CTAB), cocamidopropyl dimethylamine (CAPDMA), stearamidopropyl dimethylamine (SAPDMA), behenamidopropyl dimethylamine (BAPDMA), cetrimonium chloride (CTAC), behentrimethyl ammonium chloride (BTAC), behentrimonium methosulfate (BTMS), mixtures of the foregoing, and the like), and cholesterol; and mixing the alcohol, surfactant, and cholesterol in water to provide a total concentration of the alcohol and the surfactant in water that is approximately 5 to 35% w/w (e.g., 5.0%, 5.5%, 6.0%, 6.5%, 7.0%, 7.5%, 8.0%, 8.5%, 9.0%, 9.5%, 10.0%, 10.5%, 11.0%, 11.5%, 12.0%, 12.5%, 13.0%, 13.5%, 14.0%, 14.5%, 15.0%, 15.5%, 16.0%, 16.5%, 17.0%, 17.5%, 18.0%, 18.5%, 19.0%, 19.5%, 20.0%, 20.5%, 21.0%, 21.5%, 22.0%, 22.5%, 23.0%, 23.5%, 24.0%, 24.5%, 25.0%, 25.5%, 26.0%, 26.5%, 27.0%, 27.5%, 28.0%, 28.5%, 29.0%, 29.5%, 30.0%, 30.5%, 31.0%, 31.5%, 32.0%, 32.5%, 33.0%, 33.5%, 34.0%, 34.5%, or 35.0% w/w) and a concentration of the cholesterol that is approximately 10 to 15% w/w (e.g., 10.0%, 10.5%, 11.0%, 11.5%, 12.0%, 12.5%, 13.0%, 13.5%, 14.0%, 14.5%, or 15.0 w/w). In some embodiments, methods comprise providing and/or mixing a pH buffer in the compositions comprising an alkane, a surfactant, and cholesterol.

In some embodiments, the alcohol is stearyl alcohol, e.g., comprising cetyl alcohol and stearyl alcohol in approximately a 1:1 ratio (e.g., a “50/50” mixture of cetyl alcohol and stearyl alcohol). In some embodiments, the alcohol comprises other ratios of cetyl alcohol and stearyl alcohol ranging from approximately 1:3 to 1:1 to 3:1, e.g., in some embodiments, the alcohol comprises a mixture of cetyl alcohol and stearyl alcohol comprising 30% to 70% (e.g., 30%, 31%, 32%, 33%, 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%, 57%, 58%, 59%, 60%, 61%, 62%, 63%, 64%, 65%, 66%, 67%, 68%, 69%, or 70%) cetyl alcohol and, concomitantly, 70% to 30% (e.g., 70%, 69%, 68%, 67%, 66%, 65%, 64%, 63%, 62%, 61%, 60%, 59%, 58%, 57%, 56%, 55%, 54%, 53%, 52%, 51%, 50%, 49%, 48%, 47%, 46%, 45%, 44%, 43%, 42%, 41%, 40%, 39%, 38%, 37%, 36%, 35%, 34%, 33%, 32%, 31%, or 30%) stearyl alcohol such that the two percentages sum to 100%.

In some embodiments, the phantoms described herein are used in methods of testing, evaluating, and/or validating a magnetic resonance imaging apparatus or a plurality of magnetic resonance imaging apparatuses. In some embodiments, the phantoms described herein are used to measure within-site and/or within-sequence reproducibility of magnetic resonance imaging apparatuses and methods. In some embodiments, the phantoms described herein are used to measure multi-site reproducibility of magnetic resonance imaging apparatuses and methods.

In some embodiments, methods comprise providing a phantom as described herein (e.g., according to a method of making a phantom as described above) and obtaining magnetic resonance data using a magnetic resonance imaging apparatus. In some embodiments, methods comprise obtaining magnetic resonance data and/or calculating a magnetic resonance value that describes magnetization transfer (MT), an enhanced magnetization transfer (eMT), an inhomogeneous magnetization transfer (ihMT), an inhomogeneous magnetization transfer ratio (ihMTR), or a magnetization transfer asymmetry (MTA) for a sample (e.g., phantom as described herein). In some embodiments, magnetic resonance imaging data are provided in the form of an MT spectrum, eMT spectrum, MTA spectrum, or ihMTR spectrum.

In some embodiments, methods comprise providing a phantom comprising a composition comprising an alcohol and a surfactant at a specified total w/w concentration in water and collecting magnetic resonance data, a magnetic resonance spectrum, and/or calculating a magnetic resonance value using a magnetic resonance imaging system and the phantom. In some embodiments, methods further comprise comparing one or more of magnetic resonance data, a magnetic resonance spectrum, and/or calculating a magnetic resonance value that describes magnetization transfer (MT), an enhanced magnetization transfer (eMT), an inhomogeneous magnetization transfer (ihMT), an inhomogeneous magnetization transfer ratio (ihMTR), or a magnetization transfer asymmetry (MTA) for a sample (e.g., phantom as described herein) to previous data, a previous spectrum, and/or a previous value of magnetization transfer (MT), an enhanced magnetization transfer (eMT), an inhomogeneous magnetization transfer (ihMT), an inhomogeneous magnetization transfer ratio (ihMTR), or a magnetization transfer asymmetry (MTA) for a sample (e.g., phantom as described herein) obtained using the same magnetic resonance imaging system.

In some embodiments, methods further comprise comparing one or more of magnetic resonance data, a magnetic resonance spectrum, and/or calculating a magnetic resonance value that describes magnetization transfer (MT), an enhanced magnetization transfer (eMT), an inhomogeneous magnetization transfer (ihMT), an inhomogeneous magnetization transfer ratio (ihMTR), or a magnetization transfer asymmetry (MTA) for a sample (e.g., phantom as described herein) to data, a spectrum, and/or a value of magnetization transfer (MT), an enhanced magnetization transfer (eMT), an inhomogeneous magnetization transfer (ihMT), an inhomogeneous magnetization transfer ratio (ihMTR), or a magnetization transfer asymmetry (MTA) for a sample (e.g., phantom as described herein) obtained using a different magnetic resonance imaging system.

In some embodiments, methods further comprise comparing one or more of magnetic resonance data, a magnetic resonance spectrum, and/or calculating a magnetic resonance value that describes magnetization transfer (MT), an enhanced magnetization transfer (eMT), an inhomogeneous magnetization transfer (ihMT), an inhomogeneous magnetization transfer ratio (ihMTR), or a magnetization transfer asymmetry (MTA) for a sample (e.g., phantom as described herein) to previous data, a previous spectrum, and/or a previous value of magnetization transfer (MT), an enhanced magnetization transfer (eMT), an inhomogeneous magnetization transfer (ihMT), an inhomogeneous magnetization transfer ratio (ihMTR), or a magnetization transfer asymmetry (MTA) as known in the art or as previously published.

In some embodiments, methods further comprise comparing one or more of magnetic resonance data, a magnetic resonance spectrum, and/or calculating a magnetic resonance value that describes magnetization transfer (MT), an enhanced magnetization transfer (eMT), an inhomogeneous magnetization transfer (ihMT), an inhomogeneous magnetization transfer ratio (ihMTR), or a magnetization transfer asymmetry (MTA) for a sample (e.g., phantom as described herein) to data, a spectrum, and/or a value of magnetization transfer (MT), an enhanced magnetization transfer (eMT), an inhomogeneous magnetization transfer (ihMT), an inhomogeneous magnetization transfer ratio (ihMTR), or a magnetization transfer asymmetry (MTA) obtained for a biological sample. In some embodiments, the biological sample comprises nervous tissue or tissue associated with the nervous system (e.g., neurons and neuroglia). In some embodiments, the biological sample comprises one or more of white matter, gray matter, myelin, and/or cerebrospinal fluid. In some embodiments, the biological sample comprises one or more cell types that is/are an astrocyte, a microglial cell, an ependymal cell, an oligodendrocyte, a satellite cell, and/or a Schwann cell. In some embodiments, the biological tissue is cardiac tissue or articular cartilage.

In some embodiments, methods comparing the performance of two or more magnetic resonance imaging systems to one another. In some embodiments, methods comprise providing a first phantom comprising a composition comprising an alcohol and a surfactant at a specified total w/w concentration in water, providing a second phantom comprising the composition comprising the alcohol and the surfactant at the specified total w/w concentration in water, collecting first magnetic resonance data using a first magnetic resonance imaging system and the first phantom, collecting second magnetic resonance imaging data using a second magnetic resonance imaging system and the second phantom, and comparing the first magnetic resonance data to the second magnetic resonance data.

### Systems

Embodiments of the technology provide systems comprising a composition as described herein (e.g., a phantom as described herein). In some embodiments, the technology provides a system comprising a magnetic resonance imaging apparatus and a phantom comprising a composition as described herein. In some embodiments, the technology provides a system comprising a plurality of magnetic resonance imaging apparatuses and a phantom comprising a composition as described herein. In some embodiments, the technology provides a system comprising a plurality of magnetic resonance imaging apparatuses and a plurality of phantoms comprising a composition comprising the same components and produced according to the same methods. In some embodiments, systems further comprise a software component comprising instructions for obtaining magnetic resonance data and/or calculating a magnetic resonance value that describes magnetization transfer (MT), an enhanced magnetization transfer (eMT), an inhomogeneous magnetization transfer (ihMT), an inhomogeneous magnetization transfer ratio (ihMTR), or a magnetization transfer asymmetry (MTA) for a sample (e.g., phantom as described herein). In some embodiments, magnetic resonance imaging data are provided in the form of an MT spectrum, eMT spectrum, MTA spectrum, or ihMTR spectrum.

Although the disclosure herein refers to certain illustrated embodiments, it is to be understood that these embodiments are presented by way of example and not by way of limitation.

### EXAMPLES

### Example 1

During the development of embodiments of the technology described herein, experiments were conducted to test phantoms designed to mimic biological tissues. Data were collected from phantoms using measurements of MT, MTA, and ihMTR.

Previous work has characterized the lineshape of signals produced by compositions such as tissue that comprise water and solid or semi-solid components. For example, some analyses have indicated that a Lorentzian lineshape for the solid component did not fit the observed data and a that Gaussian (Henkelman (1993) “Quantitative interpretation of magnetization transfer” Magn Reason Med. 29(6): 759-66, incorporated herein by reference) or Super-Lorentzian (Malyarenko (2014) “Magnetization transfer in lamellar liquid crystals” Magn Reson Med. 72(5): 1427-34, incorporated herein by reference) was more appropriate. Asymmetry in the MT profile is observed at higher magnetic field strengths as chemical shift differences between water and macromolecules become provide more prominent features to the signal (Hua (2007) “Quantitative description of the asymmetry in magnetization transfer effects around the water resonance in the human brain” Magn Reson Med. 58(4): 786-93, incorporated herein by reference). Finally, rotational and translational diffusion of lipid molecules creates isolated dipolar regions, which averages intermolecular dipolar couplings between neighboring lipids and preserves intramolecular dipolar couplings along the lipid chain (Varma (2018) “Low duty-cycle pulsed irradiation reduces magnetization transfer and increases the inhomogeneous magnetization transfer effect” J Magn Reson 296: 60-71, available at doi.org/10.1016/j.jmr.2018.08.004, incorporated herein by reference; Manning (2017) “The physical mechanism of ‘inhomogeneous’ magnetization transfer MRI” J Magn Reson. 274: 125-36; and Swanson (2017) “Molecular, dynamic, and structural origin of inhomogeneous magnetization transfer in lipid membranes” Magn Reson Med. 77(3): 1318-28, each of which is incorporated herein by reference).

This physics leads to magnetization with dipolar order that contributes to the MT lineshape. Accordingly, experiments were conducted to understand the complicated contributions to the MT lineshape created by chemical shift and molecular motions. Data were collected to understand the physics of model systems, which contributes to understanding MT in vivo and aids the design of MT phantoms.

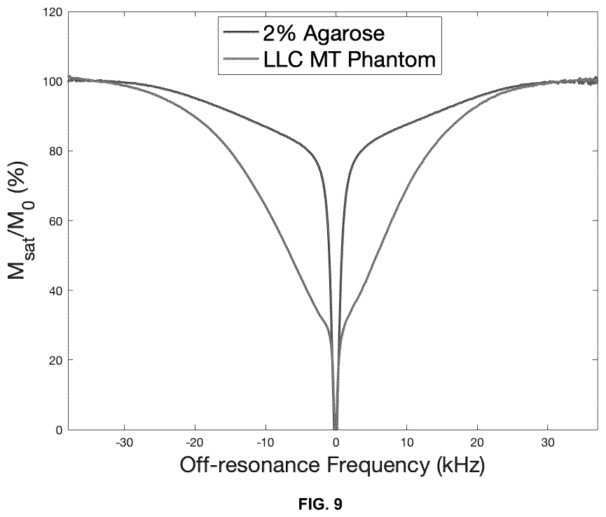

In these experiments, several materials with MT properties were studied, including agarose at 2% w/w and lipid phantoms comprising decanol, cetyltrimethyl ammonium bromide (CTAB), cetearyl alcohol (CA), behentrimethyammoniom chloride (BTAC), stearylamidopropyl dimethylamine (SD), and/or cholesterol (chop (e.g., at 12% w/w). FIG. 9 shows a comparison of agarose phantoms and phantoms comprising lamellar liquid crystal compositions as described herein.

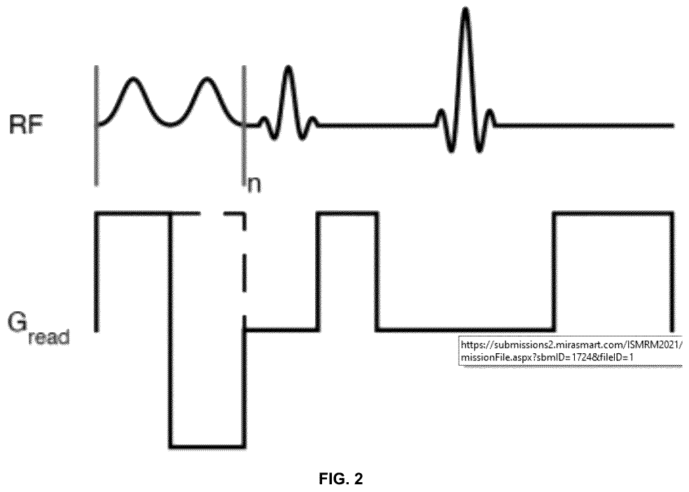

Single-shot MT z-spectra (Swanson (1991) “Broad-Band excitation and detection of cross-relaxation NMR-spectra” J Magn Reson. 95(3): 615-18, incorporated herein by reference) were acquired at 16.7 T with single-sided RF saturation (++) and (−−) generated by gradient reversal. Enhanced MT (eMT) spectra were acquired with dual-sided (+−) and (− +) RF (Swanson 1991, supra, incorporated herein by reference). MT asymmetry (MTA) was calculated as (++)−(−−) RF saturation and ihMTR as [(++)+(−−)]−[(+−)+(−+]. See, e.g., Swanson (2017), supra; and Ercan (2018) “Microstructural correlates of 3D steady-state inhomogeneous magnetization transfer (ihMT) in the human brain white matter assessed by myelin water imaging and diffusion tensor imaging” Magn Reson Med 80(6): 2402-14, each of which is incorporated herein by reference. FIG. 2 shows a schematic of the NMR pulse sequence used to generate MT and eMT z-spectra.

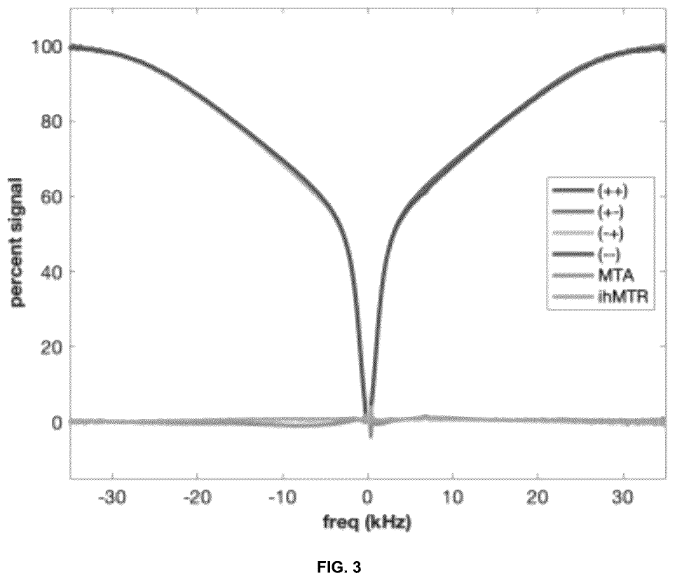

MT is often described as an exchange between free water and “bound” water. While this model is overly simple and inaccurate for most relevant biological systems, it can be used to model MT observed for a simple system comprising agarose in water. In agarose, polysaccharide strands form a double helical structure that binds structural waters that exchange with free water. Water in the agarose helix resonates at the same frequency as free water. In addition, the water is rigidly held and efficient spin-diffusion within the bound water pool creates a short dipolar order relaxation time (T1d) and small ihMT signal. Therefore agarose has minimal MT asymmetry and ihMTR (FIG. 3).

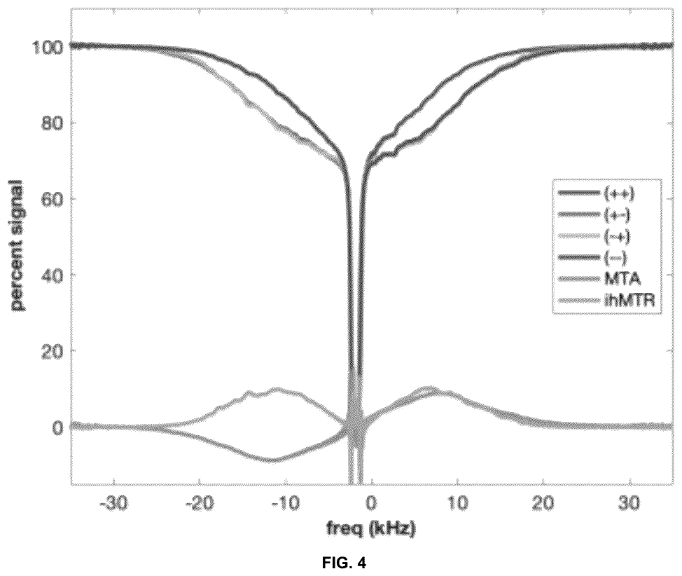

CTAB and decanol combine to form lamellar liquid crystals with demonstrated MT properties (Swanson (2017), supra). MT occurs by proton exchange between water and decanol hydroxyl protons. The MT spectra have an asymmetry generated by the chemical shift of the aliphatic chain. The difference between (++) and (−−) saturation samples provide a clear MTA signal (FIG. 4). Rapid motions of decanol average both intramolecular and intermolecular dipolar interactions resulting in a system with minimal ihMT and in which dipolar order is not established.

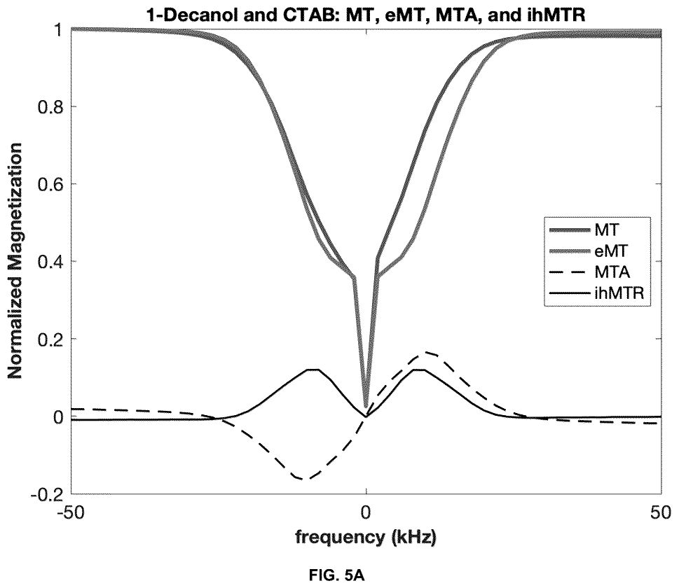

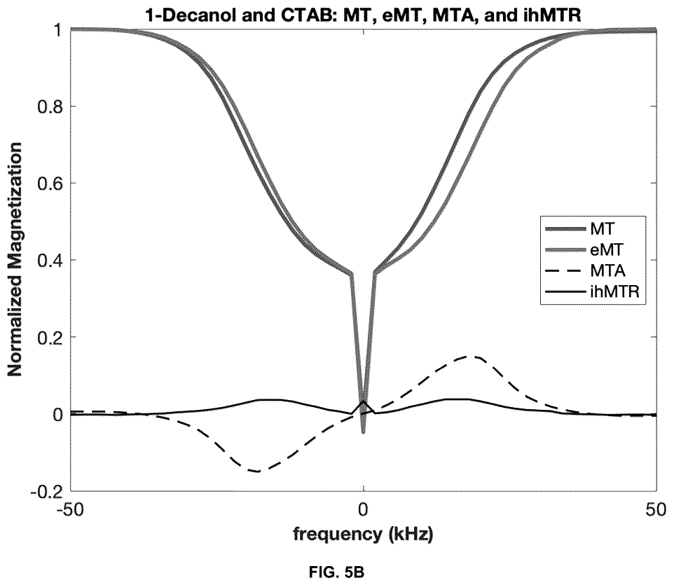

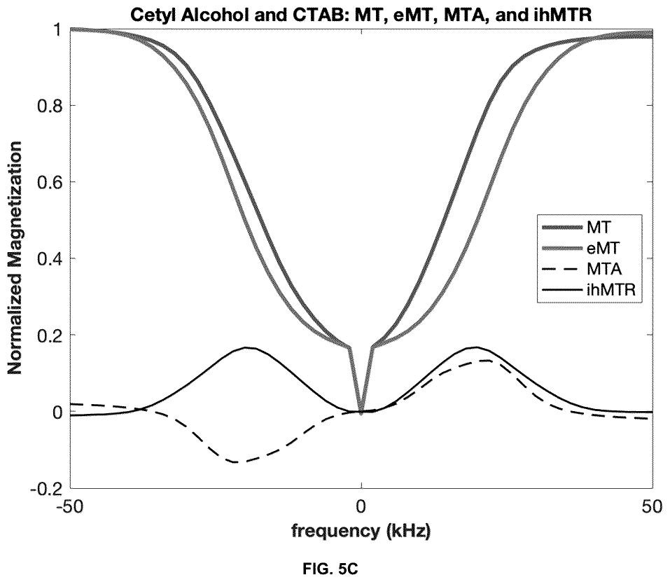

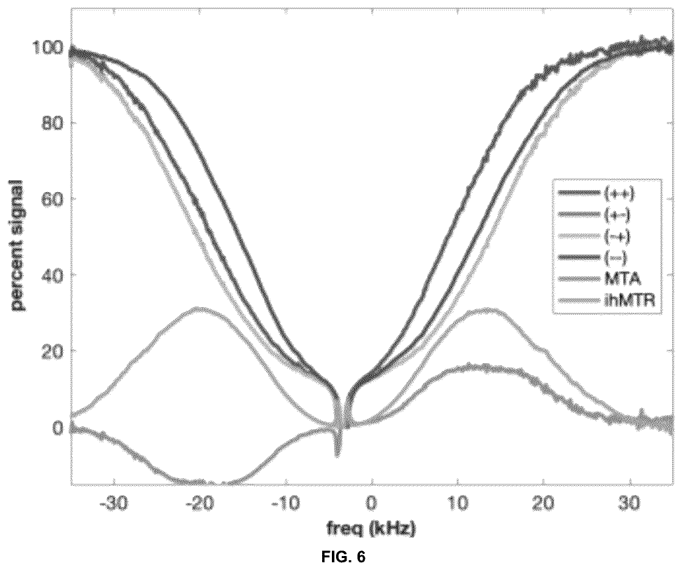

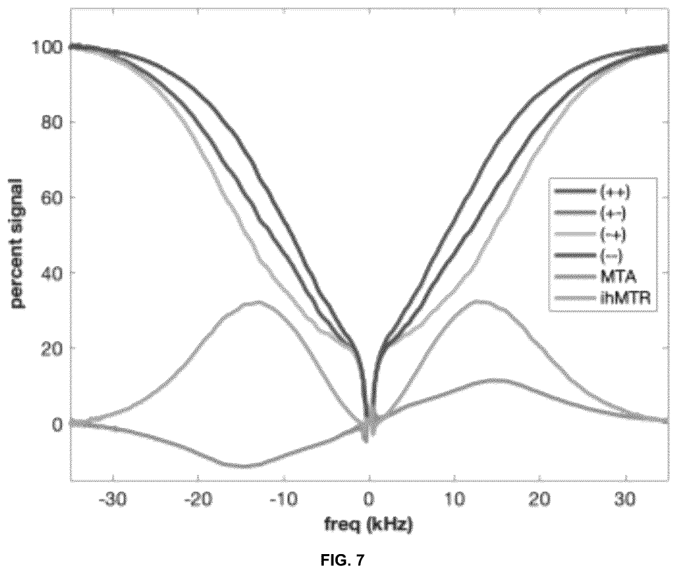

Using a higher molecular weight alcohol (e.g., cetearyl alcohol (CA)) and a non-ionic surfactant with amide groups (e.g., stearylamidopropyl dimethylamine (SD)) forms a sample with exchanging amide and hydroxyl protons (FIG. 5). The two exchanging proton groups with different underlying proton spectra balance the MT asymmetry effects and provide minimal MTA in the CA:SD:BTAC sample. Further, these conditions maximize dipolar order because the lipid chains rotate freely and thus form isolated dipolar reservoirs with long proton T1d times. Accordingly, the eMT signal is much larger than the MT signal and ihMTR is maximized. Surprisingly, the MT spectra are nearly super-Lorentzian while the eMT spectra are Gaussian. Without being bound by theory, this is contemplated to be a result described by Provotorov theory and single versus dual-sided RF saturation (Varma (2018) “Low duty-cycle pulsed irradiation reduces magnetization transfer and increases the inhomogeneous magnetization transfer effect” J Magn Reson 296: 60-71, available at doi.org/10.1016/j.jmr.2018.08.004, incorporated herein by reference; Manning (2017) “The physical mechanism of ‘inhomogeneous’ magnetization transfer MRI” J Magn Reson. 274: 125-36; and Swanson (2017) “Molecular, dynamic, and structural origin of inhomogeneous magnetization transfer in lipid membranes” Magn Reson Med. 77(3): 1318-28, each of which is incorporated herein by reference). Heating the CA:SD:BTAC sample to 50° C. causes return of the MT asymmetry (FIG. 6) due to different exchange rates between amide and hydroxyl protons. Adding cholesterol to the CA:SD:BTAC sample increases sample rigidity, adds an additional source for MTA, and decreases ihMTR (FIG. 7) with respect to CA:SD:BTAC without cholesterol (FIG. 5).

MT in vivo is complicated. The MT effect is a function of pH, chemical shift, molecular components, molecular dynamics, and experimental conditions. The MT line shape is broad, but it is not featureless. The data collected from several model systems during these experiments indicated that MT exists with or without MT asymmetry and with or without effects of dipolar order. MTA is zero for systems such as agarose with exchanging water molecules and large for systems with exchanging protons and a chemical shift from water. ihMTR is maximized in systems that preserve dipolar order but allow rotational motions of lipid molecules. Cholesterol adds rigidity, increases MTA, and decreases ihMTR.

Accordingly, these data and general principles derived therefrom are used to predict the behavior of model systems (e.g., phantoms) designed to mimic biological tissue. Thus, embodiments of the technology account for these features and principles to provide compositions that produce MT lineshapes that are similar to MT lineshapes produced in in vivo measurements. In addition, the MT data provided herein find use in providing accurate and reproducible MT phantoms, e.g., that are useful for quantitative multisite clinical studies using MTR.

### Example 2

During the development of embodiments of the technology described herein, a number of compositions were produced and tested for use as phantoms having MT signals similar to biological tissues.

A first phantom composition comprised 500 ml of deionized water, 50 g of cetearyl alcohol (CA), 12.5 g of BTAC, 10 g of stearylamidopropyl dimethylamine (SAPDA, a non-ionic surfactant), 3 ml of 85% lactic acid, 200 mg of EDTA, and 200 mg of sodium azide. The water was heated to 70° C. and the surfactants (SAPDA and BTAC), ETDA, and sodium azide were dissolved in the heated water. Lactic acid was added to protonate the SAPDA and clarify the solution. In a separate glass container, CA was melted. The aqueous solution was stirred vigorously and the melted CA was added to the stirred aqueous solution. Heat was removed, the mixture was cooled to approximately 50° C., and the viscous mixture was transferred to a 500 ml polyethylene bottle. This mixture was allowed to cool to room temperature. This mixture, termed “MT-Full”, was diluted with water to obtain a linear series of concentrations of semisolid materials to provide a linear MT phantom as described further herein (see, e.g., FIG. 5A and FIG. 5B; FIG. 6).

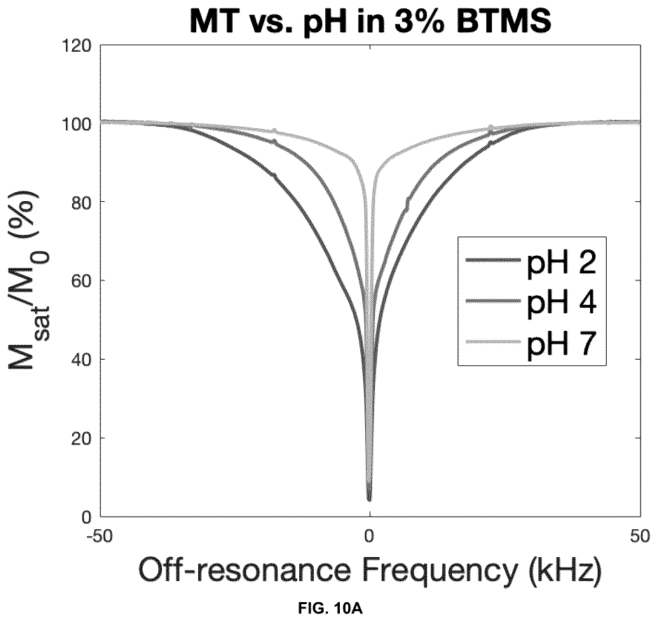

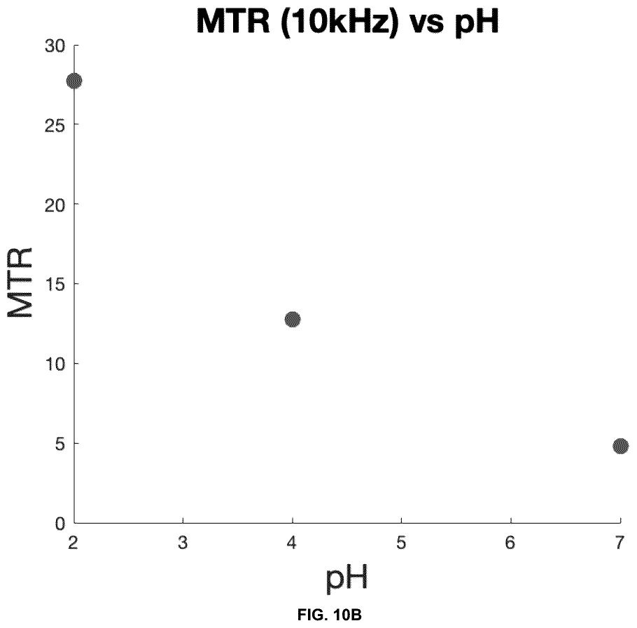

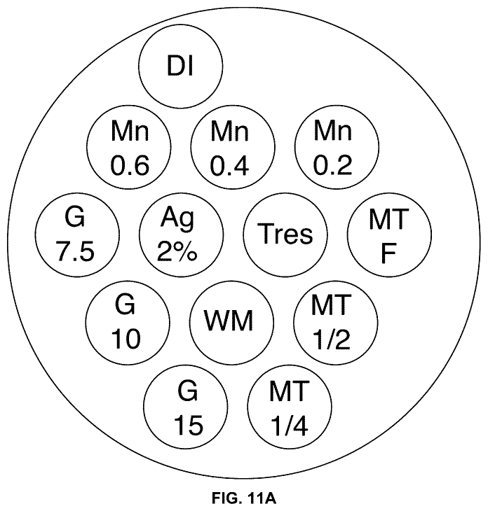

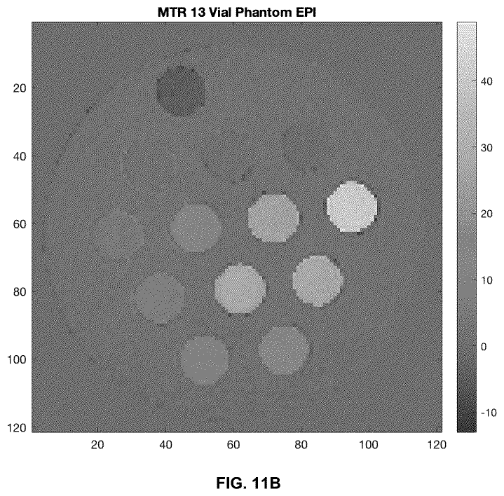

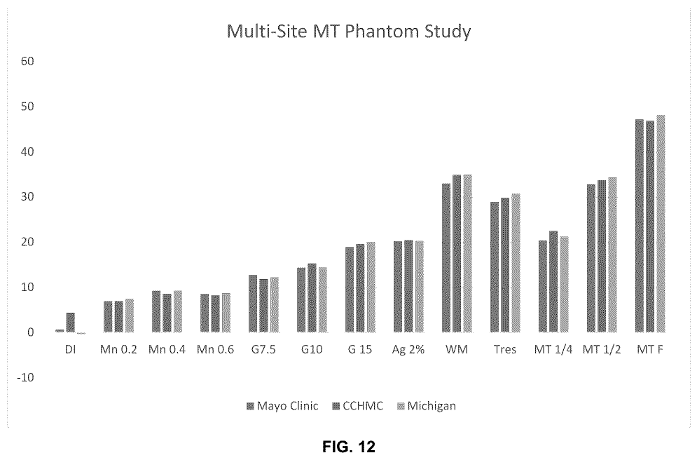

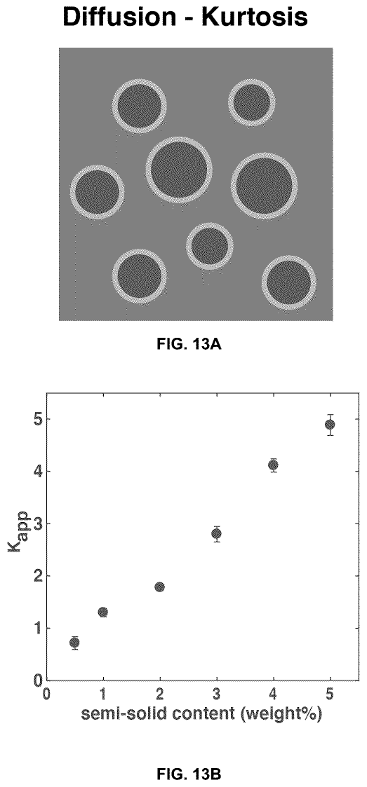

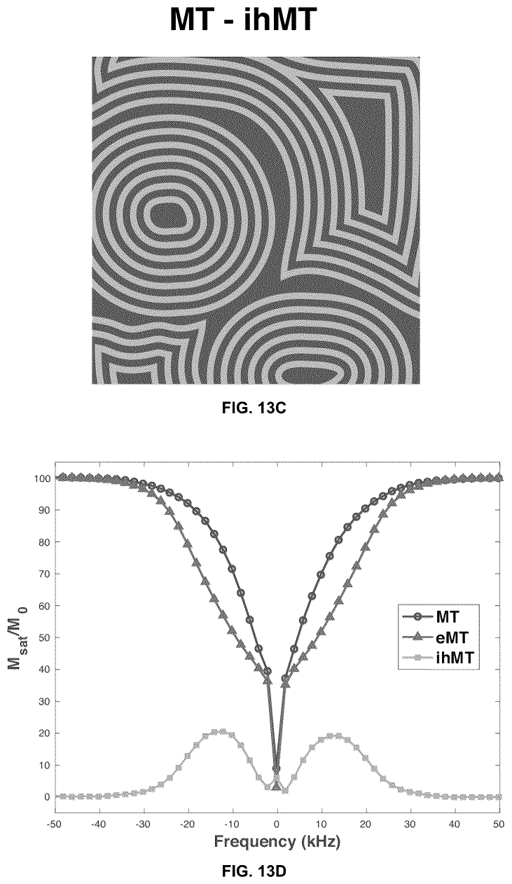

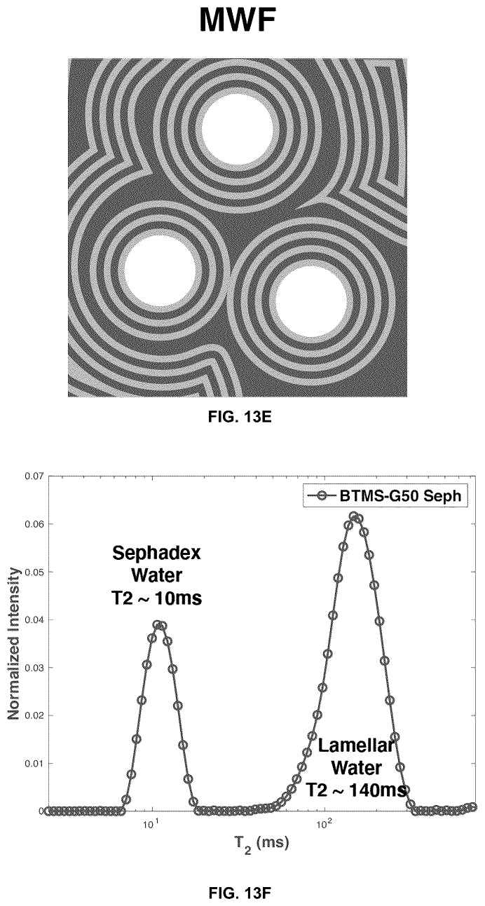

A second phantom composition comprised a 3% w/w CA:BTMS mixture. This phantom was made by melting 3 g of a 3:1 mixture of CA and behentrimethyl ammonium sulfate (BTMS) and adding the melted CA:BTMS to 100 ml of water heated to 70° C. Varying amounts of lactic acid were added to create samples at pH 2, 4, and 7. Data collected from the phantoms at these pH values are shown in FIG. 10A and FIG. 10B. The dominant mechanism of MT and magnetic coupling between solid-like and water protons is proton exchange. Proton exchange is pH catalyzed, becoming more efficient at low pH and less efficient at neutral pH. Therefore, the amount of MT present in the compositions can be adjusted by adjusting the pH, while other parameters (e.g., the semisolid content) are held constant.

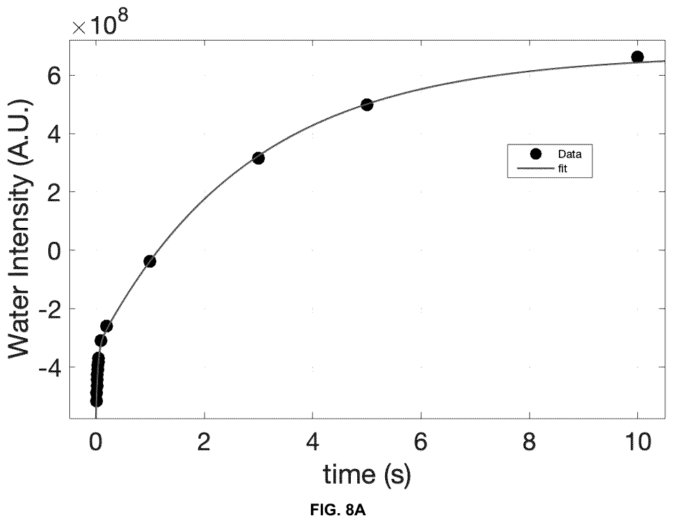

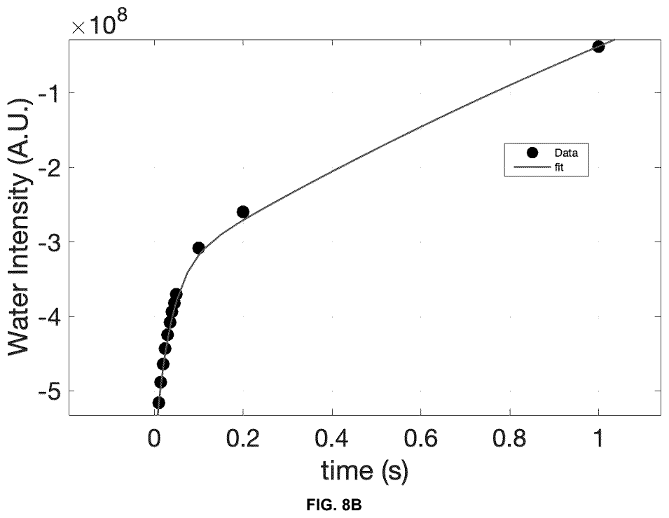

A third phantom composition was made comprising 30% semisolid material and 70 percent water, a ratio similar to white matter in vivo. This phantom was made by heating 100 ml of water and adding 30 g of melted CA:BTMS to the heated water. Measurements of this phantom composition are shown in FIG. 8A and FIG. 8B.

A fourth phantom composition was made that comprised G10 SEPHADEX suspended in a dilute solution (2% w/w) of CA:BTMS. This particular composition creates regions of short T2 times in the SEPHADEX pores and long T2 times in the lamellar regions of the phantom. The exchange time of water between the SEPHADEX and lamellar regions (short T2 and long T2) is controlled by the amount and type of lamellar network used. See FIG. 7E and FIG. 7F.

The technology also provides variations in these phantom compositions. For example, a phantom comprising a 50/50 composition of cetyl and stearyl alcohol in CA increases lipid bilayer fluidity and changes solid component T2 times. By using either pure cetyl or stearyl alcohol, a more crystalline and rigid lipid network is formed and the semisolid T2 can be decreased further. Indeed, other components such as cholesterol can also be included to provide further increase in membrane stiffness.

All publications and patents mentioned in the above specification are herein incorporated by reference in their entirety for all purposes. Various modifications and variations of the described compositions, methods, and uses of the technology will be apparent to those skilled in the art without departing from the scope and spirit of the technology as described. Although the technology has been described in connection with specific exemplary embodiments, it should be understood that the invention as claimed should not be unduly limited to such specific embodiments. Indeed, various modifications of the described modes for carrying out the invention that are obvious to those skilled in the art are intended to be within the scope of the following claims.

I claim:

1. A composition comprising an alcohol and a surfactant in water, wherein the w/w concentration of the alcohol and surfactant combined is 5% to 35%.

2. The composition of claim 1, wherein the alcohol comprises an alkane chain of 10 to 25 carbons.

3. The composition of claim 1, wherein the alcohol comprises an alkane chain of 16 or 18 carbons.

4. The composition of claim 1, wherein the alcohol is cetearyl alcohol.

5. The composition of claim 4, wherein the cetearyl alcohol comprises a 1:1 weight or molar ratio mixture of cetyl alcohol and stearyl alcohol.

6. The composition of claim 4, wherein the cetearyl alcohol comprises a mixture of cetyl alcohol and stearyl alcohol at a weight or molar ratio of from 1:3 to 3:1.

7. The composition of claim 1, further comprising cholesterol.

8. The composition of claim 7, wherein the cholesterol concentration is 10% to 15% w/w.

9. The composition of claim 1, further comprising an acid.

10. The composition of claim 1, further comprising a pH buffer.

11. The composition of claim 1, further comprising a cross-linked dextran gel.

12. The composition of claim 1, wherein the temperature of the composition is approximately 20° C. to 55° C.

13. A method comprising:
mixing a surfactant and an alcohol in water, wherein the w/w concentration of the alcohol and surfactant combined is 5% to 35%.

14. The method of claim 13, further comprising heating the water prior to said mixing.

15. The method of claim 13, further comprising heating the surfactant and alcohol prior to said mixing.

16. The method of claim 13, wherein the alcohol comprises an alkane chain of 10 to 25 carbons.

17. The method of claim 13, wherein the alcohol comprises an alkane chain of 16 or 18 carbons.

18. The method of claim 13, wherein the alcohol is cetearyl alcohol.

19. The method of claim 18, wherein the cetearyl alcohol comprises a 1:1 weight or molar ratio mixture of cetyl alcohol and stearyl alcohol.

20. The method of claim 18, wherein the cetearyl alcohol comprises a mixture of cetyl alcohol and stearyl alcohol at a weight or molar ratio of from 1:3 to 3:1.

21. The method of claim 13, further comprising mixing cholesterol into the composition.

22. The method of claim 21, wherein the cholesterol concentration in the composition is 10% to 15% w/w.

23. The method of claim 13, further comprising mixing an acid into the composition.

24. The method of claim 13, further comprising mixing a pH buffer into the composition.

25. The method of claim 13, further comprising mixing a cross-linked dextran gel into the composition.

26. A method of validating a magnetic resonance imaging apparatus or magnetic resonance imaging protocol, the method comprising:
providing a composition comprising an alcohol and a surfactant in water, wherein the w/w concentration of the alcohol and surfactant combined is 5% to 35%; and
recording magnetic resonance data using the composition and a magnetic resonance imaging apparatus.

27. The method of claim 26, wherein said magnetic resonance data comprises a measure of magnetization transfer (MT), enhanced magnetization transfer (eMT), inhomogeneous magnetization transfer (ihMT), inhomogeneous magnetization transfer ratio (ihMTR), or magnetization transfer asymmetry (MTA) for the composition.

28. The method of claim 26, wherein said magnetic resonance data comprises a quantitative measure of magnetization transfer (MT), enhanced magnetization transfer (eMT), inhomogeneous magnetization transfer (ihMT), inhomogeneous magnetization transfer ratio (ihMTR), or magnetization transfer asymmetry (MTA) for the composition.

29. The method of claim 26, further comprising comparing the magnetic resonance data to previous magnetic resonance data obtained for the same magnetic resonance imaging apparatus, for the same magnetic resonance imaging protocol, for a different magnetic resonance imaging apparatus, for a different magnetic resonance imaging protocol, or to previously published magnetic resonance data.

30. The method of claim 26, further comprising comparing the magnetic resonance data to magnetic resonance data obtained for a biological sample.

31. The method of claim 30, wherein the biological sample comprises neurons and/or neuroglia.

32. The method of claim 30, wherein the biological sample comprises one or more of white matter, gray matter, myelin, and/or cerebrospinal fluid.

33. The method of claim 30, wherein the biological sample comprises an astrocyte, a microglial cell, an ependymal cell, an oligodendrocyte, a satellite cell, and/or a Schwann cell.

34. A system comprising a composition comprising an alcohol and a surfactant in water, wherein the w/w concentration of the alcohol and surfactant combined is 5% to 35%; and a magnetic resonance imaging apparatus.

35. The system of claim 34 further comprising a software component comprising instructions for obtaining magnetic resonance data and/or calculating a magnetic resonance value that describes magnetization transfer (MT), enhanced magnetization transfer (eMT), inhomogeneous magnetization transfer (ihMT), inhomogeneous magnetization transfer ratio (ihMTR), or magnetization transfer asymmetry (MTA).
